(19) United States
(12) Patent Application Publication
(10) Pub. No.: US 2013/0214349 A1
(43) Pub. Date: Aug. 22, 2013

(54) Trench MOSFET Structure and Method of Making the Same

(71) Applicants: Jianping Gu, Shanghai (CN); Gang Ji, Shanghai (CN); Kaibin Ni, Shanghai (CN); Tianbin Zhong, Shanghai (CN)

(72) Inventors: Jianping Gu, Shanghai (CN); Gang Ji, Shanghai (CN); Kaibin Ni, Shanghai (CN); Tianbin Zhong, Shanghai (CN)

(21) Appl. No.: 13/882,255

(22) PCT Filed: Oct. 29, 2010
(86) PCT No.: PCT/CN2010/078263

§ 371 Date: Apr. 29, 2013

(30) Foreign Application Priority Data
Oct. 29, 2010 (CN) PCT/CN2010/078263

(51) Int. Cl. H01L 29/66; H01L 29/78

(52) U.S. Cl. CPC H01L 29/66666; H01L 29/7827
USPC 257/330; 438/270

(57) ABSTRACT

A trench MOSFET sidewall structure includes a heavily doped substrate, a lightly doped epitaxial layer, a lightly doped well and a heavily doped source adjacent to one another to form a semiconductor substrate. Multiple trenches as well as multiple contact holes are defined in the substrate and each contact hole respectively is defined between two adjacent trenches. A top portion of the contact hole has a size larger than that of a bottom portion of the contact hole.

### CROSS REFERENCE TO RELATED APPLICATIONS

This application claims the benefit of priority to PCT/CN2010/078263, filed on Oct. 29, 2010 under the Patent Cooperation Treaty.

### BACKGROUND OF THE INVENTION

1. Field of the invention

This invention is related to a trench MOSFET structure, and more particularly, to the structure of a sidewall of a trench MOSFET with high density cell.

2. Description of Related Art

Power metal oxide semiconductor field-effect transistor, MOSFET, is widely used in 4C products, such as communication, computer, consumer and car) for fast switching speed, high frequency, high input resistance, low drive power, low temperature and no secondary penetration.

Every trench power MOSFET product is composed of multiple MOSFET units and each MOSFET unit is called a cell. The distance between two adjacent cells is called the pitch which is an important electrical parameter to directly influence reducing drain-source on-resistance (Rdson). Reducing drain-source on-resistance (Rdson) is the total resistance in a unit area between the source and the drain of a device when in operation, which is a decisive factor for determining the rated current and power, especially in mid/low power MOSFET product. The more the number of the cell is, the less the Rdson is. Therefore, it is practical for product consuming even smaller power.

Following the shrinking of dimension and size of the package, the area of MOSFET is also decreasing. In order to maintain the number of the cell high, the pitch needs to be reduced. With reference to FIG. 1, a cross sectional view of a current trench power MOSFET is shown. Two trenches 3 are defined and filled with polysilicone. An insulation layer 4 is formed on top of the trenches 3 via depositing ILD (inter layer dielectric). A contact hole 1 of the source is sandwiched between the two trenches 3 and penetrating through the highly doped source area 6.

According to the currently available technique, the distance between two adjacent cells (pitch) is not smaller than 1.3 μm and the contact hole 1 for the source is not smaller than 0.35 μm. If the size continues to shrink, the current technique suffers from the following problems:
1. The line width after photolithography for the source (DICD) is close to or similar to the width of the contact hole of the source after etching (FICD). When the FIDC is small enough, the corresponding DICD needs to be small as well to the extent equivalent to that of FIDC. As a result of the DICD being smaller and smaller to match with FIDC, the line width after photolithography for the source (DICD) is limited by the resolution of lithography, which also limits the pitch to continue to shrink.
2. The alignment and overlay of the drain and the source (DT-CT overlay) affects greatly on the line width “d” of the source (gap between the source contact hole 1 and drain trench 3), which easily causes line width unbalance between two sides of the source contact hole 1 and affects the electricity of the MOSFET.
3. When the source contact hole 1 is small enough to cause the aspect ratio too big to allow the metal to properly fill into the source contact hole and void is thus generated. To cope with this problem, tungsten is required to fill into the source contact hole, which greatly increases the difficulty of the technique involved.

Under the premise of preserving the quality of MOSFET, reducing the pitch and lowering Rdson of MOSFET have become quite a lesson for the industry.

### SUMMARY OF THE INVENTION

The primary objective of the present invention is to provide a sidewall structure of the trench MOSFET to resolve the resolution limitation caused by lithography to the pitch of the trench MOSFET cells.

Another objective of the present invention is to provide a method for making a sidewall structure of the trench MOSFET to resolve the resolution limitation caused by lithography to the pitch of the trench MOSFET cells.

To accomplish the aforementioned objectives, the sidewall structure of the trench MOSFET includes a heavily doped substrate, a lightly doped extension, a lightly doped drain and a heavily doped source sequentially adjacent to one another to form a substrate of a semiconductor, multiple drain trenches and multiple source contact holes each of which is sandwiched between two adjacent drain trenches. Two sides of every top opening of each source contact hole is provided with a slanted surface to make the size of the top opening of every source contact hole being larger than that of a bottom opening thereof.

According to the preferred embodiment of the trench MOSFET sidewall structure of the present invention, an ILD insulation is formed on top of each drain trench. The ILD insulation is closely adjacent to the sidewall structure of the trench MOSFET to form the slanted surface.

According to the preferred embodiment of the trench MOSFET sidewall structure of the present invention, the coverage rate of the ILD insulation to the bottom sidewall is 30%˜85%.

According to the preferred embodiment of the trench MOSFET sidewall structure of the present invention, thickness of the ILD insulation is 3000 \acute{Å}˜5000 \acute{Å}.

According to the preferred embodiment of the trench MOSFET sidewall structure of the present invention, each sidewall includes an oxide layer and a silicon nitride layer. The silicon nitride layer is formed on sides of the source contact hole and the oxide layer is sandwiched between bottom of the silicon nitride and top face of the heavily doped source.

According to the preferred embodiment of the trench MOSFET sidewall structure of the present invention, thickness of the second oxide layer is 200˜500 \acute{Å}.

According to the preferred embodiment of the trench MOSFET sidewall structure of the present invention, height of the silicon nitride layer is 1800˜5000 \acute{Å} and thickness of the silicon nitride layer is 1000˜10000 \acute{Å}.

According to the preferred embodiment of the trench MOSFET sidewall structure of the present invention, each trench is filled with polysilicon and the filled polysilicon has a height larger than that of the heavily doped source and the sidewalls are formed on sides of the filled polysilicon which is higher than that of the heavily doped source.

According to the preferred embodiment of the trench MOSFET sidewall structure of the present invention, thickness of the filled polysilicon is 2000˜50000 \acute{Å}.

Still another objective of the present invention is to provide a method for making a trench MOSFET sidewall, the method includes the steps of:

providing a heavily doped substrate;

forming a lightly doped epitaxial layer;

forming a lightly well on the lightly doped epitaxial layer;

defining trenches penetrating through the lightly doped well and adjacent to the lightly doped epitaxial layer;

forming a heavily doped source on top of the lightly doped well and between the trenches;

forming sidewalls on sides of the lightly well; and

defining source contact hole with top opening being larger than bottom opening via self-alignment of the sidewalls.

According to the preferred embodiment of the method for marking a trench MOSFET sidewall structure of the present invention, the trench defining step includes the steps of:

depositing a first oxide layer on top of the lightly doped well;

defining multiple recesses penetrating through the oxide layer and the lightly doped well and reaching the lightly doped epitaxial layer;

filling polysilicon into the recesses; and

removing the oxide layer to form the trenches.

According to the preferred embodiment of the method for making a trench MOSFET sidewall structure of the present invention, thickness of the first oxide layer is 2500˜5000 \acute{Å}.

According to the preferred embodiment of the method for making a trench MOSFET sidewall structure of the present invention, the sidewall forming step includes the steps of:

forming a second oxide layer on top of the heavily doped well;

depositing silicon nitride on the oxide layer and each of the trenches; and

forming the sidewall via etching.

According to the preferred embodiment of the method for making a trench MOSFET sidewall structure of the present invention, thickness of the second oxide layer is 200˜500 \acute{Å}.

According to the preferred embodiment of the method for making a trench MOSFET sidewall structure of the present invention, height of the silicon nitride layer formed on sides of the trenches is 1800˜5000 \acute{Å} and thickness of the silicon nitride layer is 1000˜10000 \acute{Å}.

According to the preferred embodiment of the method for making a trench MOSFET sidewall structure of the present invention, the step of depositing a silicon nitride layer on sides of the trenches includes the steps of:

filling polysilicon into the recesses to have the filled polysilicon higher than that of the heavily doped source; and

depositing a silicon nitride layer on sides of the polysilicon of the heavily doped source.

According to the preferred embodiment of the method for making a trench MOSFET sidewall structure of the present invention, thickness of the filled polysilicon is 2000˜5000 \acute{Å}.

According to the preferred embodiment of the method for making a trench MOSFET sidewall structure of the present invention, further steps include:

depositing an ILD insulation layer on the trenches and the sidewalls;

partially removing the ILD insulation layer to allow the ILD insulation layer to cover the trenches and part of the sidewalls to form the slanted surface with the sidewall.

According to the preferred embodiment of the method for making a trench MOSFET sidewall structure of the present invention, the coverage rate of the ILD insulation to the bottom sidewall is 30%˜85%.

According to the preferred embodiment of the method for making a trench MOSFET sidewall structure of the present invention, thickness of the ILD insulation is 3000 \acute{Å}˜5000 \acute{Å}.

According to the preferred embodiment of the method for making a trench MOSFET sidewall structure of the present invention, the formation of the ILD insulation is completed by depositing an oxide and borophosphosilicate glass, BPSG via PECVD.

According to the preferred embodiment of the method for making a trench MOSFET sidewall structure of the present invention, the source contact hole is defined via the coverage of the sidewall and etching. The source contact hole reaches the lightly doped well after penetrating through the heavily doped source.

To sum up, the advantage of the present invention includes:
1. The source contact hole constructed in accordance with the preferred embodiment of the present invention is characterized in that a size of the top opening of the source contact hole is larger than that of the bottom opening such that the current available technique used in large line width is available for making source contact hole with smaller size and the pitch is greatly reduced as well as the diminishing of MOSFET Rdson.
2. The larger size of the top opening of the source contact hole readily facilitates the filling of metal(s) and effectively avoids generation of any unnecessary voids. Under the premise of having the source contact hole being small, aluminum-cupper (Al—Cu) or Al—Si—Cu alloy is still suitable for making the metal layer, which reduces the difficulty of the technique.
3. The distance between the source contact hole and the trench is determined by self-alignment of the sidewall and not limited by any lithography device limitations such that the source contact hole is precisely positioned at center of two adjacent trenches.
4. The sidewall of the preferred embodiment of the present invention is formed by the second oxide layer and the silicon nitride layer and because the second oxide layer is situation between the silicon nitride layer and the heavily doped source, stress between the sidewall and the heavily doped source is avoided.

### BRIEF DESCRIPTION OF THE DRAWINGS

The preferred embodiment(s) of the invention, as well as its many advantages, may be further understood by the following detailed description and accompanying drawings.

FIG. 1 is a cross sectional view showing the structure of a trench power MOSFET;

FIG. 2 is a schematic top plan view showing the trench power MOSFET of the preferred embodiment of the present invention;

FIG. 3 is a cross sectional view showing the partial structure of the trench power MOSFET of the preferred embodiment of the present invention;

FIG. 4 is a flow chart showing the steps of the method of the present invention;

FIG. 5 is a schematic view showing the first step of the method of the present invention;

FIG. 6 is a schematic view showing the second step of the method of the present invention;

FIG. 7 is a schematic view showing the third step of the method of the present invention;

FIG. 8 is a schematic view showing the fourth step of the method of the present invention;

FIG. 9 is a schematic view showing the fifth step of the method of the present invention;

FIG. 10 is a schematic view showing the sixth step of the method of the present invention;

FIG. 11 is a schematic view showing the seventh step of the method of the present invention;

FIG. 12 is a schematic view showing the eighth step of the method of the present invention; and

FIG. 13 is a schematic view showing the ninth step of the method of the present invention.

### DETAILED DESCRIPTION OF THE INVENTION

The primary objective of the preferred embodiment of the present invention is to make the source contact hole to have the upper portion of the source contact hole a first size and the lower portion of the source contact hole a second size being smaller than that of the first size so as to reduce the pitch between cells and MOSFET Rdson.

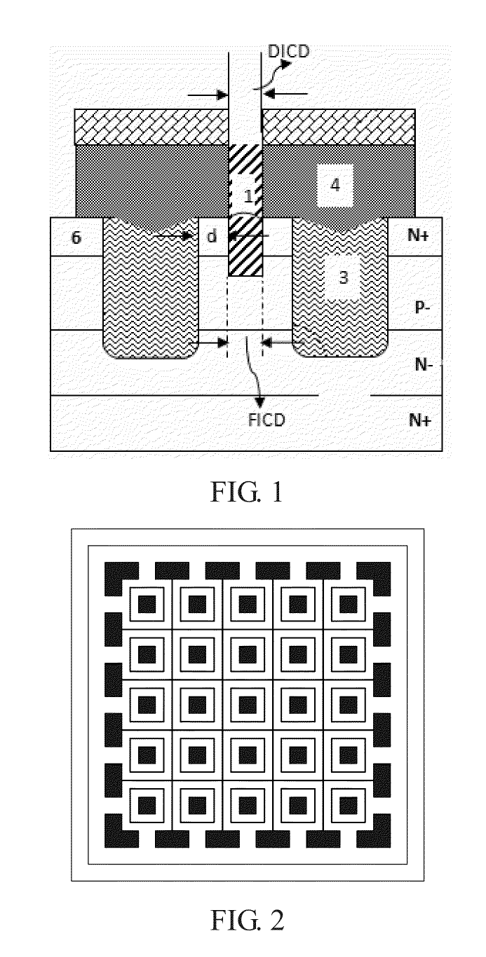

With reference to FIG. 2, a preferred embodiment of the trench MOSFET structure is shown and has multiple cells 21 indicated in square areas. The distance between two adjacent cells is called the pitch and the resistance of the channel below the cell is the channel resistance which is the most important parameter in drain in open state. When the drain in a MOSFET is open, current passes through the channel below the gate. As a result, when the pitch becomes smaller and smaller, more and more cells are accommodated in a single unit area and the channel resistance is smaller. Again, the smaller the channel resistance is, the smaller the Rdson is, which is the primary objective of the present invention.

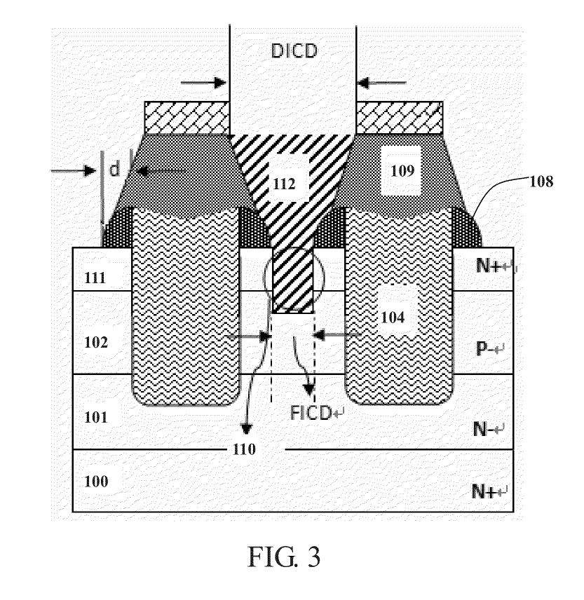

With reference to FIG. 3, the substrate of the trench MOSFET is composed of a heavily doped substrate 100, a lightly doped epitaxial layer 101, a lightly doped well 102 and a heavily doped source 111 respectively adjacent to one another. Two trenches 104 are defined in the substrate and extended through the heavily doped source 111 and the lightly doped well 102 to engage with the lightly doped epitaxial layer 101. Polysilicon is filled into the trenches and the filled polysilicon has a height higher than that of the heavily doped source 111, which is 2000˜5000 \acute{Å}.

A contact hole 110 is defined between the two trenches and extended through the heavily doped source 111 and engaged with the lightly doped well 102. Metal such as Al—Si—Cu or Al—Cu is filled into the contact hole 110. A sidewall 108 is formed surrounding sides of the polysilicon above the trenches 104 and has a certain angle to allow the size of the upper portion of the source contact hole 110 larger than that of the lower portion of the source contact hole such that the source contact hole 110 has a flare shape.

An ILD insulation layer 109 is formed on top of the trenches 104 above the polysilicon and has a thickness of 3000˜5000 \acute{Å}. A sidewall of the insulation layer 109 is slanted to mate with the sidewall 108 such that the size of the upper portion of the source contact hole 110 is increased. The ILD insulation layer 109 has a coverage rate of 30˜85% to the sidewall 108.

In addition, to avoid stress between the sidewall 108 and the heavily doped source 111, the sidewall 108 may be formed by the oxide layer (not labeled for being almost invisible) and silicon-nitride layer which is formed on sides of the source contact hole 110 to have an angle. The oxide layer is formed at the bottom of the silicon-nitride layer and on the top surface of the heavily doped source 111. The oxide layer has a thickness of 200˜500 \acute{Å}. The silicon-nitride layer has a height of 1800˜5000 \acute{Å} and a thickness of 1000˜10000 \acute{Å}.

Due to the flare shape of the source contact hole 110, the actual size of the source contact hole 110 is determined by slope of the sidewall 108 alone or by combination of the sidewall 108 and the ILD insulation layer 109. As a result of the fact, the currently available commercial lithography method is read for making contact holes with small dimensions. Contrast to the conventional lithography method, the size of the contact hole defined in according to the method of the preferred embodiment of the present invention is not limited by the line width and determined by the distance between the sidewalls 108, which is advantageous for reducing the size of the contact hole 110 as well as the pitch in MOSFET so as to increase the density of the cells and accomplish the purpose of reducing power consumption. It is noted that the trench MOSFET structure is especially suitable for making power MOSFET with a pitch smaller than 1.3 μm to accomplish the objective of high cell density and low power MOSFET.

Furthermore, the existence of the sidewall 108 fulfills the self-alignment of the source contact hole 110 and the trenches 104 so as to effectively control the position of the source contact hole 110 at the center of two adjacent gates and avoid the shift of the source contact hole 110 due to overlay. In addition, the flared shape of the source contact hole 110 facilitates the filling of metal into the contact hole 110. Even when the size of the source contact hole 110 becomes small, it is still possible to adopt Al—Cu or Al—Si—Cu as the material for filling to effectively avoid generation of void during the filling process and the yield is thus increased.

The above description serves only an explanatory purpose and should not be interpreted as limitations. For example, the slope of the sidewall 108 is adjustable according to requirements. In addition, when the size of the source contact hole is large enough, the ILD insulation layer may even be omitted and only the sidewall is left. The metal material for the source contact hole may also be replaced with other appropriate metallic materials.

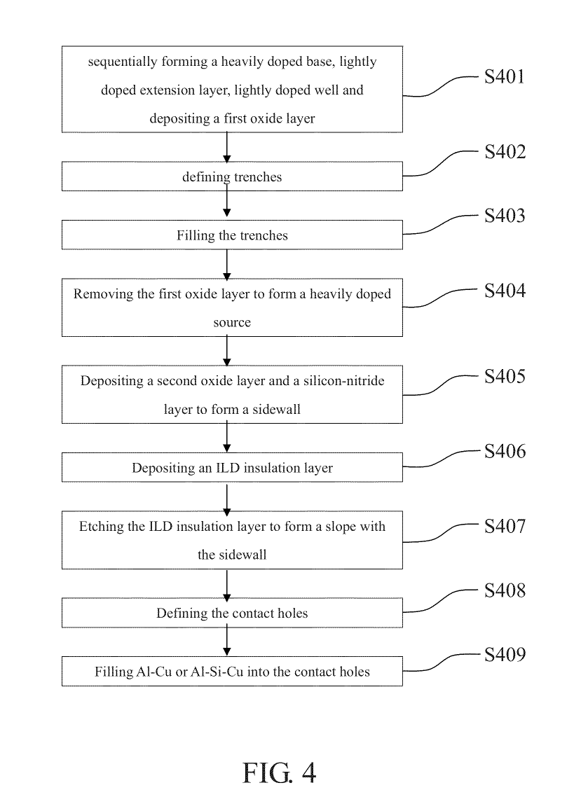

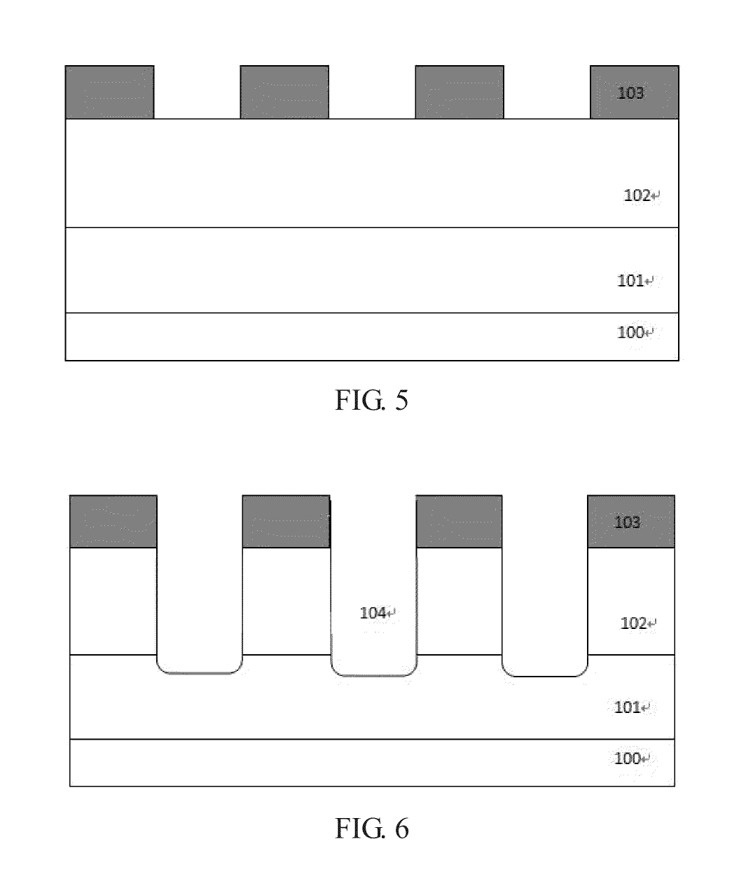

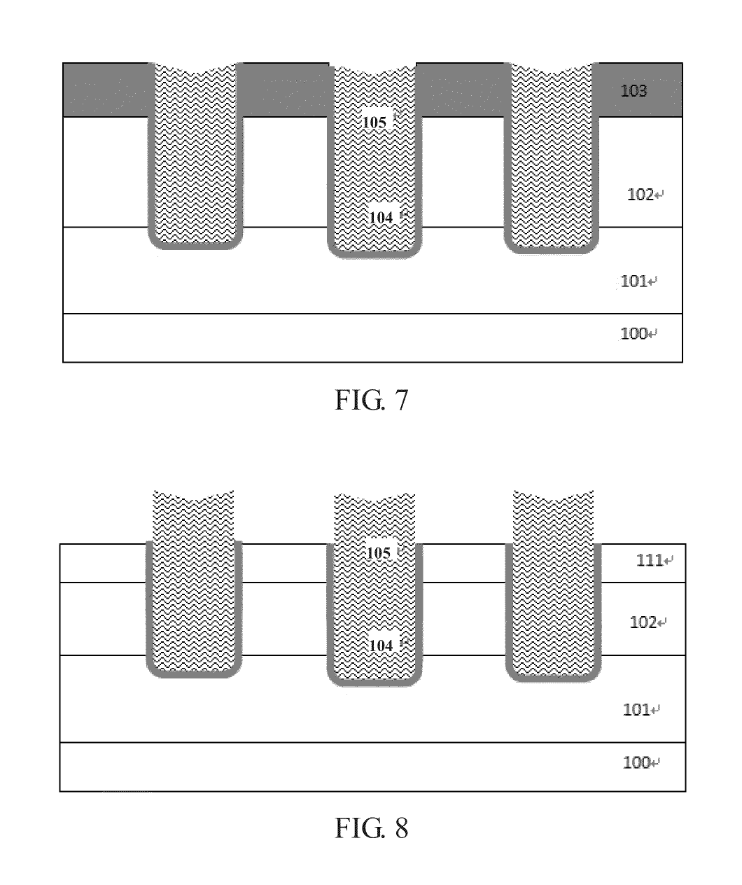

With reference to FIG. 4 as well as FIGS. 5˜13, a preferred embodiment of the method for making a trench MOSFET in accordance with the present invention includes the steps of:

S401: providing a heavily doped substrate 100; forming a lightly doped epitaxial layer 101 on top of the heavily doped substrate; forming a lightly well 102 on the lightly doped epitaxial layer; depositing a first oxide layer 103 (wherein the first oxide layer 103 has a thickness of 2500˜5000 \acute{Å}), as shown in FIG. 5;

S402: defining trenches 104 penetrating through the lightly doped well 102 and adjacent to the lightly doped epitaxial layer 101 with the assistance of the first oxide layer 103 (as shown in FIG. 6);

S403: oxidizing and filling polysilicon 105 into the trenches 104 and the top of the first oxide layer 103 (in which, polysilicon 105 is labeled on the top and trench 104 is labeled at the bottom), removing (via such as CMP) excessive first oxide layer 103 and remaining the polysilicon inside the trenches 104, wherein the polysilicon inside the trenches 104 and the first oxide layer 103 are flush in height;

S404: wet etching the first oxide layer 103 to allow the polysilicon 105 inside the trenches 104 higher than that of the lightly doped well 102, wherein the height is 2500˜5000 \acute{Å} and forming a heavily doped source 111 on top of the lightly doped well 102 and between the trenches 104 via ionization;

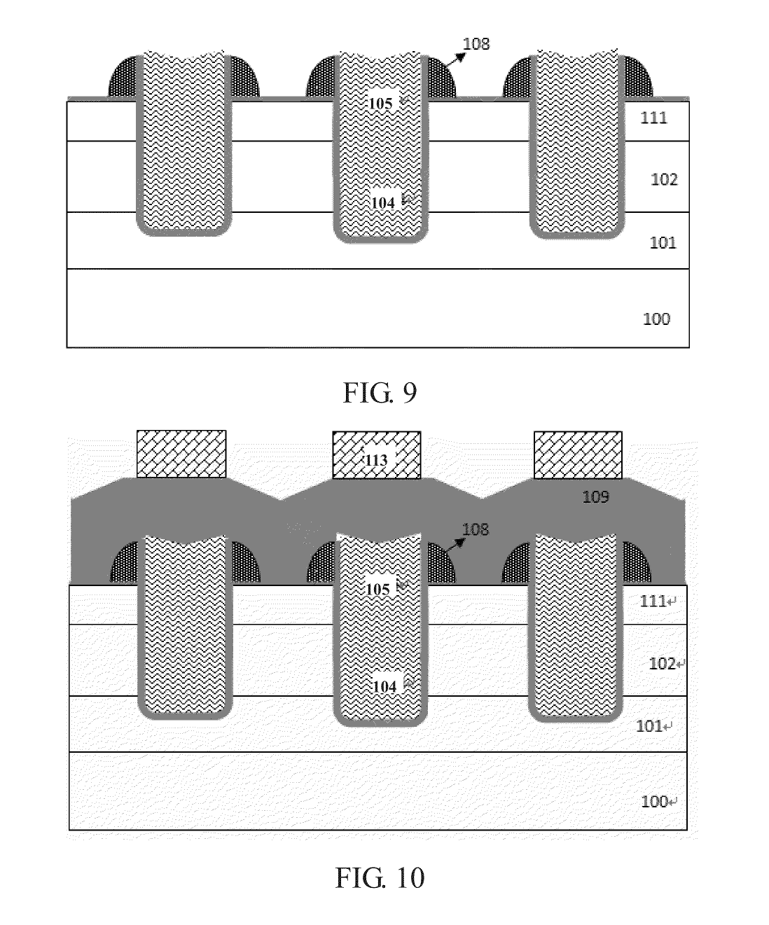

S405: forming a second oxide layer with a thickness of 200˜500 \acute{Å} on top of the heavily doped source 111, forming a silicon-nitride layer on top of the second oxide layer and on sides of the trenches 104, wherein the silicon-nitride layer has a height of 1800˜5000 \acute{Å}, and thickness of 1000˜10000\acute{Å}, and forming a sidewall 108 via etching, wherein the sidewall 108 is composed of the second oxide layer and the silicon-nitride layer, as shown in FIG. 9;

S406: depositing an ILD insulation layer 109 on top of the trenches 104 and the sidewall 108, wherein the ILD insulation layer 109 may be formed via PECVD the oxide layer and BPSG and having a thickness of 3000˜5000 \acute{Å}; and forming a layer of photoresist layer 113 on top of the ILD insulation layer 109, as shown in FIG. 10;

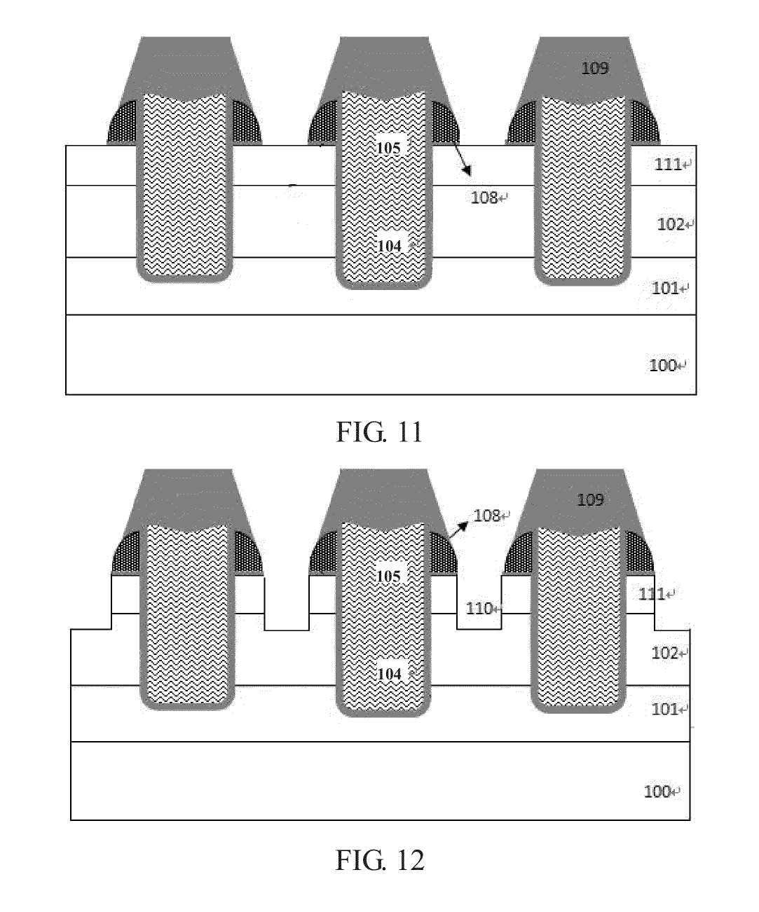

S407: using the photoresist layer 113 to etch the ILD insulation layer 109 to make the side of the ILD insulation layer slanted and in a rate of 30%˜85 to cover the sidewall 108 and the polysilicon, wherein the ILD insulation layer 109 and the sidewall 108 together form the slope, as shown in FIG. 11;

S408: using the ILD insulation layer 109 and the sidewall 108 as mask to define a source contact hole 110 penetrating through the heavily doped source 111 and engaging lightly doped well 102, as shown in FIG. 12;

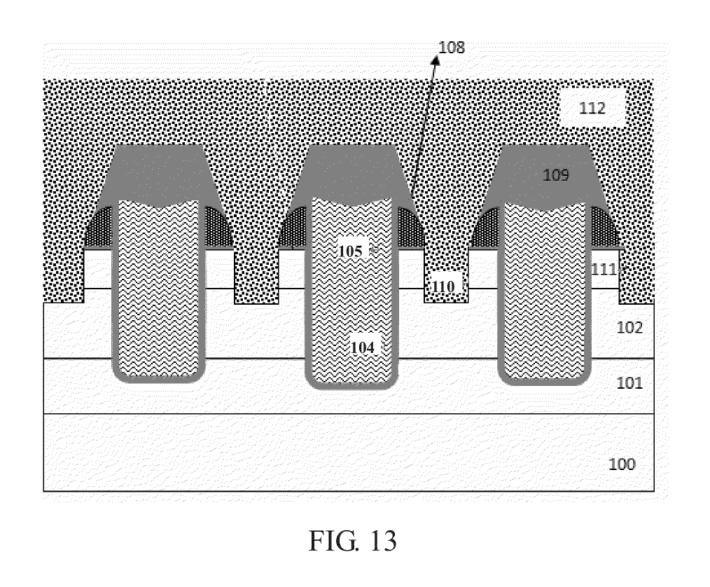

S409: depositing Al—Cu or Al—Si—Cu 112 with a height of 8000˜14000 \acute{Å}, as shown in FIG. 13.

The manufacture method previously described is only a preferred embodiment of the present invention and the sequence of the steps of the method can be alternated or changed in accordance with the requirements of the technique available at the time of making. Also, the parameters involved in the method of the invention can be adjusted accordingly.

Based on the currently available MOSFET structure and the related art, the preferred embodiment of the present invention changes the contact hole structure, which is helpful in the facilitation of the filling of the Al—Cu or Al—Si—Cu into the contact hole as well as the use of lithography in making power MOS tube with the size of smaller than 1.3 μm.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A trench MOSFET sidewall structure composed of a heavily doped substrate, a lightly doped epitaxial layer, a lightly doped well and a heavily doped source adjacent to one another to form a semiconductor substrate, multiple trenches as well as multiple contact holes defined in the substrate and each contact hole respectively being defined between two adjacent trenches, wherein the improvements comprise:
each contact hole having a slanted sidewall formed on a top portion of the contact hole to allow a size of the top portion of the contact hole being larger than that of a bottom portion of the contact hole.

2. The structure as claimed in claim 1, wherein an ILD insulation layer is formed on top of each of the trenches and connected to the sidewall to form a slope.

3. The structure as claimed in claim 2, wherein the ILD insulation layer has a coverage rate of 30%˜85% to the sidewall.

4. The structure as claimed in claim 2, wherein the ILD insulation layer has a thickness of 3000˜5000 \acute{Å}.

5. The structure as claimed in claim 1, wherein each sidewall has a first oxide layer and a silicon-nitride layer, the silicon-nitride layer is formed on sides of the contact hole and the first oxide layer is formed between the silicon-nitride layer and the heavily doped source.

6. The structure as claimed in claim 5, wherein the first oxide layer has a thickness of 200˜500 \acute{Å}.

7. The structure as claimed in claim 5, wherein the silicon-nitride layer has a height of 1800˜5000 \acute{Å} and a thickness of 1000˜10000 \acute{Å}.

8. The structure as claimed in claim 1, wherein polysilicon is filled into the trenches and has a height larger than that of the heavily doped source, the sidewall is formed on sides of the polysilicon that is higher than the heavily doped source.

9. The structure as claimed in claim 8, wherein the polysilicon which is higher than that of the heavily doped source has a thickness of 2000˜5000 \acute{Å}.

10. A method for making a trench MOSFET sidewall comprising the steps of:
forming a heavily doped substrate;
forming a lightly doped epitaxial layer on the heavily doped substrate;
forming a lightly well on the lightly doped epitaxial layer;
defining multiple trenches extending through the lightly doped well and engaging with the lightly doped epitaxial layer;
forming a heavily doped source on top of the lightly well and between two adjacent trenches;
forming a sidewall on sides of each of the trenches;
forming contact holes via self-alignment of the sidewall, wherein a top portion of each contact hole has a size larger than that of a bottom portion of the contact hole.

11. The method as claimed in claim 10, wherein the trench defining step further has the steps of:
depositing a first oxide layer on the lightly doped well;
defining multiple recesses extending through the first oxide layer and the lightly doped well and reaching the lightly doped epitaxial layer;
filling polysilicon into the recesses; and
removing the first oxide layer to form the trenches.

12. The method as claimed in claim 11, wherein the first oxide layer has a thickness of 2500˜5000 \acute{Å}.

13. The method as claimed in claim 10, wherein the sidewall forming step further has the steps of:
depositing a second oxide layer on the heavily doped source;
depositing a silicon-nitride layer on the second oxide layer and sides of each of the trenches; and
forming the sidewall via etching.

14. The method as claimed in claim 13, wherein the second oxide layer has a thickness of 200˜500 \acute{Å}.

15. The method as claimed in claim 13, wherein the silicon-nitride layer formed on the sides of each of the trenches has a height of 1800˜5000 \acute{Å} and a thickness of 1000˜10000 \acute{Å}.

16. The method as claimed in claim 13, wherein the silicon-nitride layer depositing step has the steps of:
filling polysilicon in the recesses to allow the filled polysilicon to have a height larger than that of the heavily doped source; and
depositing a silicon-nitride layer on sides of the filled polysilicon.

17. The method as claimed in claim 16, wherein the filled polysilicon has a thickness of 2000˜5000 \acute{Å}.

18. The method as claimed in claim 10 further comprising steps of:
depositing an ILD insulation layer on top of the trenches and the sidewall;
dry etching the ILD insulation layer to allow the ILD insulation layer to cover the trenches and a part of the sidewall so as to form a slope with the sidewall.

19. The method as claimed in claim 18, wherein the ILD insulation layer has a coverage rate of 30%˜85% to the sidewall.

20. The method as claimed in claim 18, wherein the ILD insulation layer has a thickness of 3000˜5000 \acute{Å}.

21. The method as claimed in claim 18, wherein the ILD insulation layer is formed via PECVD depositing an oxide layer and BPSG.

22. The method as claimed in claim 10, wherein the contact hole is defined via dry etching with the sidewall as mask, the contact hole extends through the heavily doped source and engages with the lightly doped well.
